(19) United States
(12) Patent Application Publication
(10) Pub. No.: US 2024/0234482 A9
(43) Pub. Date: Jul. 11, 2024

(54) MICROELECTRONIC DEVICES INCLUDING CAPACITORS, AND RELATED ELECTRONIC SYSTEMS AND METHODS

(71) Applicant: Micron Technology, Inc., Boise, ID (US)

(72) Inventors: Sanket S. Kelkar, Sunnyvale, CA (US); Michael Mutch, Chardon, OH (US); Luca Fumagalli, Rio Rancho, NM (US); Hisham Abdussamad Abbas, Meridian, ID (US); Brenda D. Kraus, Boise, ID (US); Dojun Kim, Boise, ID (US); Christopher W. Petz, Boise, CA (US); Darwin Franseda Fan, Boise, ID (US)

(21) Appl. No.: 18/047,978

(22) Filed: Oct. 19, 2022

(51) Int. Cl. H01L 49/02; H01G 4/008; H01G 4/12; H01L 27/108

(52) U.S. Cl. CPC H01L 28/75; H01G 4/008; H01G 4/1218; H01L 27/10814; H01L 27/10852

(57) ABSTRACT

A microelectronic device comprises an access device comprising a source region and a drain region spaced from the source region, an insulative material vertically adjacent to the access device, and a capacitor within the insulative material and in electrical communication with the access device. The capacitor comprises a material comprising silicon oxynitride or titanium silicon nitride over surfaces of the insulative material, a first electrode comprising titanium nitride on the material, a dielectric material over the first electrode, and a second electrode on the dielectric material. Related methods of forming the microelectronic device and an electronic system including the microelectronic devices are also described.

### TECHNICAL FIELD

The disclosure, in various embodiments, relates generally to the field of microelectronic device design and fabrication. More specifically, the disclosure relates to microelectronic devices including capacitors comprising a seed material, and to related electronic systems and methods of forming the microelectronic devices.

### BACKGROUND

A continuing goal of integrated circuit fabrication is to increase integration density. Dynamic random-access memory (DRAM) utilizes DRAM capacitors to store an amount of electrical charge that represents the logical value of a stored bit. Some DRAM capacitors include container-shaped capacitors having one electrode shaped as a container, with a cell dielectric material and another electrode on the inside of the container only (e.g., a single-sided hole capacitor), or on the outside of the container only (e.g., a single-sided pillar capacitor, or on both the inside and outside of the container (e.g., a double-sided container). To increase integration density, the lateral footprint of the DRAM capacitors has been reduced by increasing the aspect ratio (i.e., ratio of height to width or diameter) and decreasing the proximity of adjacent DRAM capacitors to one another. The high aspect ratio and smaller dimensions have led to structurally weak containers that are prone to toppling or breaking. The container-shaped capacitors have a hollow, cylindrical shape anchored at the top and bottom but are capable of lateral movement, which causes deformation of (e.g., damage to) the DRAM capacitor. Therefore, the structural stability and mechanical strength of the container (e.g., the bottom electrode) is significant to the operability of the DRAM capacitor in the DRAM device.

Titanium nitride (TiN) has been used as an electrode material in DRAM capacitors due to its good step coverage and interfacial properties with the cell dielectric material of the DRAM device. The TiN also exhibits good mechanical, chemical inertness, and electrical resistance (e.g., low resistance) properties. With the decreasing size of the DRAM capacitors, TiN bottom electrodes of the DRAM capacitors have decreased in thickness. However, the reduced thickness of the TiN bottom electrode impacts the surface area of the DRAM capacitors and increases the susceptibility of the TiN to problems associated with oxidation. As the thickness of the TiN decreases, the resistance (Rs) increases exponentially, limiting the use of TiN as an electrode material in smaller DRAM capacitors. The TiN bottom electrodes also provide support and mechanical strength during the fabrication of the DRAM capacitors. With the decreasing size of the DRAM capacitors, retaining structures (e.g., lattice structures) have been used to strengthen the TiN bottom electrode, by supporting exterior sidewalls of the containers defined by the TiN bottom electrodes. However, using the retaining structures increases the complexity of the DRAM capacitor fabrication process.

An additional problem associated with the use of TiN as the bottom electrode is dielectric induced bottom electrode bending (DIBB). As the dimensions of the DRAM capacitors decrease, DIBB increases. DIBB is caused by tensile external forces exerted on the TiN during crystallization of the cell dielectric material of the DRAM capacitor. DIBB is also caused by compressive stresses induced in the DRAM capacitor during oxidative processes conducted during the DRAM capacitor fabrication process, such as pre-treatment processes, dielectric deposition processes, and post-treatment processes.

Silicon-doped TiN has been used as an oxygen diffusion barrier material in a single-sided DRAM capacitor that includes polysilicon or hemispherical polysilicon as the material of the bottom electrode and tantalum oxide as the cell dielectric material. The silicon-doped titanium nitride provides oxidation protection to the polysilicon bottom electrode during rapid thermal annealing of the tantalum oxide cell dielectric material. Incorporating silicon into the titanium nitride was determined to remove the columnar structure of the TiN and undesirably increase the resistivity of the TiN.

Boron-doped TiN has been used as a bottom electrode material in a single-sided metal-insulator-metal capacitor that includes aluminum oxide as the cell dielectric material. The boron-doped TiN is formed over a hemispherical polysilicon material.

### BRIEF DESCRIPTION OF THE DRAWINGS

FIG. 1A is a simplified partial cross-sectional view of a microelectronic device, in accordance with embodiments of the disclosure;

FIG. 1B is a simplified partial cross-sectional view of a storage device of the microelectronic device of FIG. 1A, in accordance with embodiments of the disclosure;

FIG. 1C is a simplified partial cross-sectional view of a storage device of the microelectronic device of FIG. 1A, in accordance with additional embodiments of the disclosure;

FIG. 2 is a simplified flow diagram illustrating a method of forming a storage device, in accordance with embodiments of the disclosure;

FIG. 3 is a simplified flow diagram illustrating a method of forming a storage device, in accordance with additional embodiments of the disclosure;

FIG. 4 is a schematic block diagram of an electronic system, in accordance with an embodiment of the disclosure.

FIG. 5 is a graph illustrating the relationship of the thickness of a deposited titanium nitride material and the surface coverage for titanium nitride formed on a pretreated surface and titanium nitride formed on an untreated surface;

FIG. 6A is a graph comparing the resistivity of titanium nitride formed on a pretreated silicon oxynitride surface to the resistivity of titanium nitride formed on an untreated silicon dioxide surface; and

FIG. 6B is a graph comparing the sheet resistance of titanium nitride formed on a pretreated silicon oxynitride surface to the sheet resistance of titanium nitride formed on an untreated silicon dioxide surface.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

The materials described herein may be formed by conventional techniques including, but not limited to, spin coating, blanket coating, chemical vapor deposition (CVD), atomic layer deposition (ALD), plasma enhanced ALD, physical vapor deposition (PVD), plasma enhanced chemical vapor deposition (PECVD), or low pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessary limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Jr), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped poly silicon, conductively doped germanium (Ge), conductively doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓ N_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

As used herein, “semiconductor material” or “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

According to embodiments described herein, a microelectronic device includes memory cells each comprising an access device (e.g., a transistor) and a storage device (e.g., a capacitor) operably coupled to the access device. In some embodiments, the storage device comprises a capacitor including a first electrode in electrical communication with the access device, a dielectric material, and a second electrode spaced from the first electrode by the dielectric material. In some embodiments, the capacitor comprises a so-called “container capacitor.” A seed material is located between the first electrode and a material on which the first electrode is formed (e.g., an insulative material defining at least some sidewalls of the container in which the capacitor is formed, a conductive material on which the first electrode is formed, both). Forming the seed material modifies a surface of the material on which the first electrode is formed, enabling a material of the first electrode to be formed with increased uniformity and continuity at a reduced thickness. By treating the material on which the first electrode is formed with the seed material before forming the first electrode, electrical performance properties of the first electrode may be improved. The seed material comprises a material formulated and configured to facilitate a template on which the first electrode may be formed at a relatively thin thickness while exhibiting improved surface coverage and electrical conductivity (e.g., low resistivity). In some embodiments, the seed material comprises a nitride (e.g., an oxynitride, a metal nitride, both), such as a nitride of the substrate on which the seed material is formed. In some embodiments, the seed material comprises silicon oxynitride. In other embodiments, the seed material comprises a metal of the first electrode. By way of non-limiting example, the seed material may comprise titanium silicon nitride and the first electrode may comprise titanium nitride. The seed material may not negatively impact resistivity properties of the first electrode.

In some embodiments, the seed material is formed by ALD. In some embodiments, the seed material is formed by exposing the material on which the first electrode is formed to a nitridization process to form the nitride on the surface of the material on which the seed material and the first electrode are formed. In some embodiments, the seed material is formed by exposing the material to a nitrogen source (e.g., one or more of nitrogen gas, ammonia, and hydrazine, such as nitrogen gas and ammonia) to form, for example, the seed material comprising silicon oxynitride. In some embodiments, the nitrogen source comprises a plasma. In other embodiments, the seed material is formed by exposing the material to a titanium-containing gas, a silicon-containing gas, and a nitrogen-containing gas to form the seed material comprising titanium silicon nitride. A first electrode comprising titanium nitride is formed on the seed material. In some embodiments, the first electrode has a thickness less than about 20.0 Å. In some embodiments, the seed material comprises a template on which the first electrode is formed and facilitates forming the first electrode at the relatively thin thickness while maintaining a relatively lower resistivity and lower sheet resistance than first electrode materials formed on a base material without the seed material. Accordingly, the capacitors according to embodiments of the disclosure may be formed at a smaller pitch and with smaller dimensions without negatively affecting the electrical properties of the capacitors (e.g., the conductivity of the first electrode). Thus, microelectronic devices comprising the memory cells having a smaller pitch and smaller dimensions may be formed without negatively impacting the performance of the capacitors.

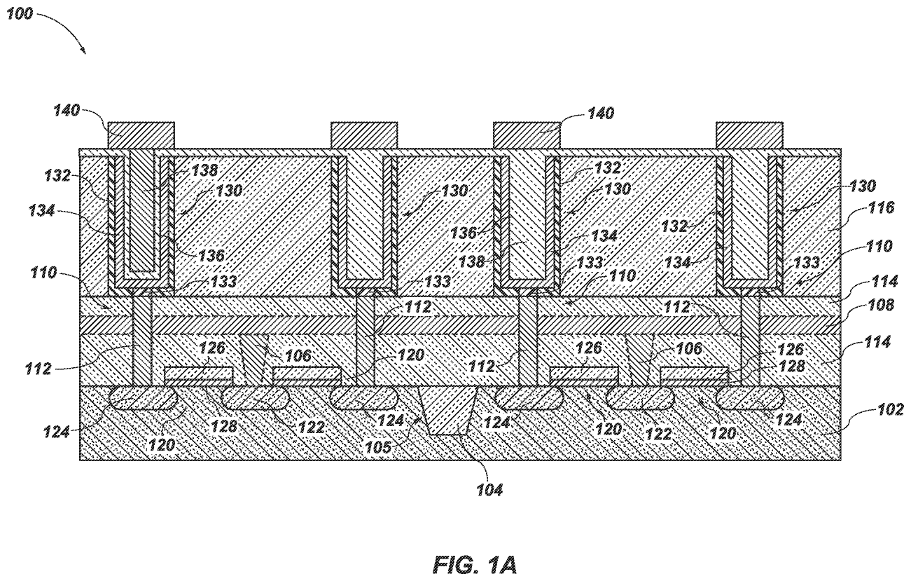

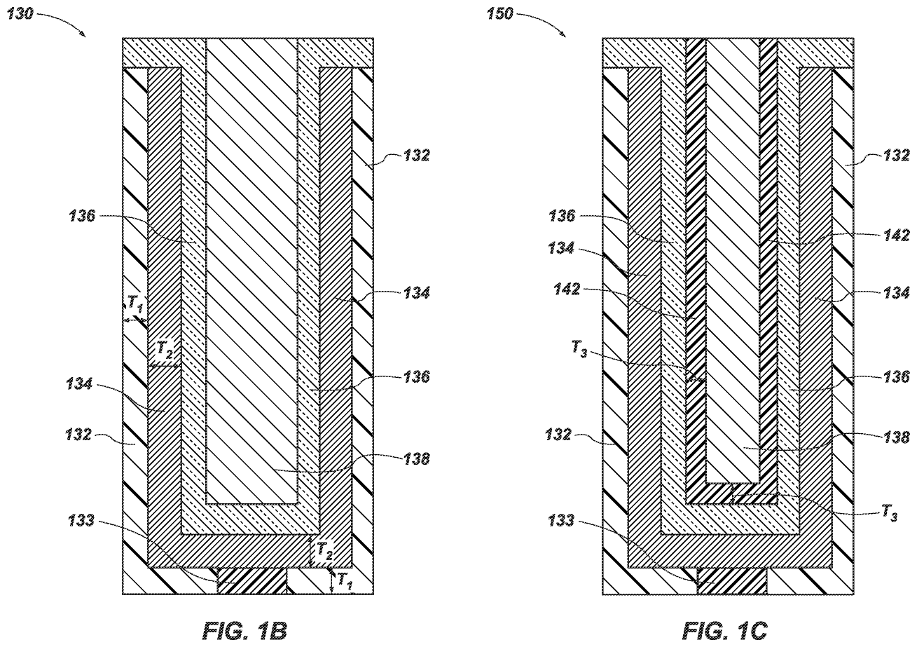

FIG. 1A is a simplified partial cross-sectional view of a microelectronic device 100 (e.g., a memory device, such as a DRAM device), in accordance with embodiments of the disclosure. With the description provided below, it will be readily apparent to one of ordinary skill in the art that the methods and structures described herein with reference to FIG. 1A may be used in various devices and electronic systems.

The microelectronic device 100 includes an array region comprising memory cells 110 vertically overlying (e.g., in the Z-direction) a base structure 102. The base structure 102 may include a conventional silicon substrate (e.g., a conventional silicon wafer), or another bulk substrate comprising a semiconductive material. As used herein, the term “bulk substrate” means and includes not only silicon substrates, but also silicon-on-insulator (SOI) substrates, such as silicon-on-sapphire (SOS) substrates and silicon-on-glass (SOG) substrates, epitaxial layers of silicon on a base semiconductive foundation, and other substrates formed of and including one or more semiconductive materials (e.g., one or more of a silicon material, such monocrystalline silicon or polycrystalline silicon; silicon-germanium; germanium; gallium arsenide; a gallium nitride; and indium phosphide). In some embodiments, the base structure 102 comprises a silicon wafer.

In some embodiments, the base structure 102 includes different materials, structures, devices, and/or regions formed therein and/or thereon. In some embodiments, the base structure 102 includes complementary metal-oxide-semiconductor (CMOS) circuitry and devices configured for effectuating operation of the memory cells 110 of the microelectronic device 100.

Each of the memory cells 110 may individually comprise a transistor 120 (e.g., an access transistor) operably coupled to a storage device 130 (e.g., a capacitor). Each of the transistors 120 may individually comprise a source region 122 and a drain region 124 horizontally neighboring (e.g., in the X-direction) the source region 122. In some embodiments, each of the source region 122 and the drain region 124 are located within the base structure 102.

In some embodiments, each of the source regions 122 and the drain regions 124 individually comprises one or more semiconductive materials doped with at least one conductivity enhancing chemical species, such as at least one N-type dopant (e.g., one or more of arsenic, phosphorous, antimony, and bismuth) or at least one P-type dopant (e.g., one or more of boron, aluminum, and gallium). The source region 122 may comprise a conductively doped region doped with at least one N-type dopant or at least one P-type dopant. In some such embodiments, the drain regions 124 comprise a conductively doped region doped with the other of the at least one N-type dopant and the at least one P-type dopant. In some embodiments, the conductively doped regions comprise conductively doped silicon, such as conductively doped polysilicon. Channel regions of the transistors 120 may be horizontally interposed (e.g., in the X-direction) between one of the source regions 122 and one of the drain regions 124.

The transistors 120 each individually includes a gate structure 126 vertically overlying (e.g., in the Z-direction) the base structure 102 and individually horizontally extending (e.g., in the X-direction) between a source region 122 and a drain region 124. In some embodiments, the gate structures 126 are horizontally aligned (e.g., in the X-direction) with and shared by channel regions of multiple transistors 120 horizontally neighboring (e.g., in the Y-direction) one another. In some embodiments, the gate structures 126 horizontally extend in a first horizontal direction (e.g., in the Y-direction).

The gate structures 126 may individually be formed of and include a conductive material, such as one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity. In some embodiments, the gate structures 126 comprise titanium. In other embodiments, the gate structures 126 comprise titanium nitride. In yet other embodiments, the gate structures 126 comprise tungsten.

A dielectric material 128 (also referred to as a “gate dielectric material”) may be vertically interposed (e.g., in the Z-direction) between the gate structures 126 and portions of the base structure 102 at least partially defining the channel regions of the transistors 120. The dielectric material 128 may be formed of and include one or more of phosphosilicate glass, borosilicate glass, borophosphosilicate glass (BPSG), fluorosilicate glass, silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride, another gate dielectric material, a dielectric carbon nitride material (e.g., silicon carbon nitride (SiCN)), a dielectric carboxynitride material (e.g., silicon carboxynitride (SiOCN)), or combinations thereof. In some embodiments, the dielectric material 128 comprises silicon dioxide.

With continued reference to FIG. 1A, an isolation structure 105 horizontally intervenes between some of the horizontally neighboring transistors 120 and electrically isolates different portions of the transistors 120 and memory cells 110 from one another. The isolation structure 105 may be referred to herein as a “shallow trench isolation structure.” The isolation structure 105 comprises a first insulative material 104.

The first insulative material 104 may be formed of and include an insulative material, such as one or more of an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof), and amorphous carbon. In some embodiments, the first insulative material 104 comprises silicon dioxide.

The source regions 122 of the transistors 120 are individually in electrical communication with first conductive interconnect structures 106. The first conductive interconnect structures 106 may individually electrically couple a source region 122 to a conductive line 108. In some embodiments, the source regions 122 of transistors 120 horizontally neighboring one another in a first horizontal direction (e.g., in the X-direction) and horizontally aligned in a second horizontal direction (e.g., in the Y-direction) are in electrical communication with the same conductive line 108.

The conductive line 108 may comprise a data line (e.g., a digit line, a bit line). The conductive line 108 may extend in a first horizontal direction (e.g., in the X-direction) and may be substantially perpendicular to a second horizontal direction (e.g., in the Y-direction) in which the gate structures 126 extend.

Each of the first conductive interconnect structures 106 and the conductive lines 108 may individually be formed of and include a conductive material, such as one or more of the materials described above with reference to the gate structures 126. In some embodiments, the first conductive interconnect structures 106 and the conductive lines 108 individually comprise tungsten. In other embodiments, the first conductive interconnect structures 106 and the conductive lines 108 individually comprise titanium nitride. In yet other embodiments, the first conductive interconnect structures 106 and the conductive lines 108 individually comprise copper.

Second conductive interconnect structures 112 individually electrically connect the drain regions 124 of the transistors 120 to the storage devices 130. The second conductive interconnect structures 112 may be formed of and include a conductive material, such as one or more of the materials described above with reference to the gate structures 126. In some embodiments, the second conductive interconnect structures 112 individually comprise tungsten. In other embodiments, the second conductive interconnect structures 112 individually comprise titanium nitride. In yet other embodiments, the second conductive interconnect structures 112 individually comprise copper.

Each of the gate structures 126, the first conductive interconnect structures 106, the second conductive interconnect structures 112, and the conductive lines 108 may be formed within a second insulative material 114. The second insulative material 114 may electrically isolate the gate structures 126, the first conductive interconnect structures 106, the second conductive interconnect structures 112, and the conductive lines 108 from one another.

The second insulative material 114 may be formed of and include an insulative material, such as one or more of the materials described above with reference to the first insulative material 104. In some embodiments, the second insulative material 114 comprises silicon dioxide.

In FIG. 1A, the first conductive interconnect structures 106 and the conductive line 108 are illustrated in broken lines to indicate that they are located in a different cross-section than the cross-section illustrated in FIG. 1A. In other words, in some embodiments, the first conductive interconnect structures 106 and the conductive line 108 are located in a different plane than the gate structures 126 and the second conductive interconnect structures 112.

With continued reference to FIG. 1A, the storage devices 130 may each individually be in electrical communication with the drain regions 124 of the transistors 120 by means of the second conductive interconnect structures 112. The storage devices 130 may be formed within a third insulative material 116 adjacent to (e.g., vertically adjacent to) the second insulative material 114. The third insulative material 116 may be formed of and include an insulative material, such as one or more of the materials described above with reference to the first insulative material 104. In some embodiments, the third insulative material 116 comprises an oxide material, such as silicon dioxide.

FIG. 1B is a simplified enlarged cross-sectional view of one of the storage devices 130 of FIG. 1A. With reference to FIG. 1A and FIG. 1B, the storage devices 130 may each individually comprise a seed material 132 (also referred to as a “first seed material”) vertically overlying (e.g., in the Z-direction) and horizontally neighboring (e.g., in the X-direction) at least a portion of the second insulative material 114, a second seed material 133 (also referred to as an “additional seed material”) vertically overlying (e.g., in the Z-direction) and horizontally neighboring (e.g., in the X-direction) the seed material 132, a first electrode material 134 vertically overlying (e.g., in the Z-direction) and horizontally neighboring (e.g., in the X-direction) the seed material 132 and the vertically overlying (e.g., in the Z-direction) the second seed material 133, a dielectric material 136 vertically overlying (e.g., in the Z-direction) and horizontally neighboring (e.g., in the X-direction) the first electrode material 134, and a second electrode material 138 vertically overlying (e.g., in the Z-direction) and horizontally neighboring (e.g., in the X-direction) the dielectric material 136. Accordingly, the storage devices 130 each individually comprise the seed material 132, the first electrode material 134, the dielectric material 136, and the second electrode material 138.

In some embodiments, the seed material 132 vertically intervenes (e.g., in the Z-direction) between the second insulative material 114 and the first electrode material 134 and horizontally intervenes (e.g., in the X-direction) between the third insulative material 116 and the first electrode material 134; the first electrode material 134 vertically intervenes (e.g., in the Z-direction) and horizontally intervenes (e.g., in the X-direction) between the seed material 132 and the dielectric material 136; and the dielectric material 136 vertically intervenes (e.g., in the Z-direction) and horizontally intervenes (e.g., in the X-direction) between the first electrode material 134 and the second electrode material 138. The second seed material 133 may vertically intervene (e.g., in the Z-direction) between the second conductive interconnect structure 112 and the first electrode material 134.

The seed material 132 and the second seed material 133 may individually be formulated and configured to facilitate nucleation of the first electrode material 134 during formation (e.g., deposition) of the first electrode material 134. In some embodiments, the seed material 132 facilitates nucleation of the first electrode material 134 when the second insulative material 114 and the third insulative material 116 comprise an oxide material, such as silicon dioxide. In some embodiments, the second seed material 133 facilitates nucleation of the first electrode material 134 directly overlying and within horizontal boundaries (e.g., in the X-direction) of the second conductive interconnect structure 112. Without being bound by any theory, it is believed that the improved nucleation of the first electrode material 134 facilitates a relatively higher uniformity and surface coverage of the seed material 132 and the first electrode material 134 on surfaces of the second insulative material 114 and the third insulative material 116 compared to conventional storage devices 130 that lack (e.g., do not include) the seed material 132. In addition, it is believed that the improved nucleation of the first electrode material 134 facilitates a relatively higher uniformity and surface coverage of the second seed material 133 on surfaces of the second conductive interconnect structure 112.

The seed material 132 may directly contact the second insulative material 114 and the third insulative material 116. In some embodiments, the seed material 132 comprises at least one element (e.g., chemical element of the periodic table) of the second insulative material 114 or the third insulative material 116 (depending on the location of the portion of the seed material 132 (e.g., whether the portion is in contact with the second insulative material 114 or the third insulative material 116)), at least one element of the first electrode material 134, or both. In some embodiments, the seed material 132 comprises at least one element of the second insulative material 114 and the third insulative material 116. In some such embodiments, the seed material 132 comprises silicon oxynitride (SiON). In other embodiments, the seed material 132 comprises at one element of the first electrode material 134. In some such embodiments, the seed material 132 comprises a metal silicon nitride (MₓSi_{y}N_{z}, wherein M is a metal, and x and y individually are integers or non-integers depending on the specific metal). The metal may comprise one or more of titanium, tungsten, tantalum, niobium, or molybdenum. In some embodiments, the metal comprises titanium and the seed material 132 comprises titanium silicon nitride (TiSiN).

The second seed material 133 may directly contact the second conductive interconnect structure 112, the seed material 132, and the first electrode material 134. In some embodiments, the second seed material 133 comprises at least one element (e.g., chemical element of the periodic table) of the second conductive interconnect structure 112, at least one element of the first electrode material 134, or both. In some embodiments, the second seed material 133 comprises a metal nitride of a metal element of the second conductive interconnect structure 112. In some embodiments, the second seed material 133 comprises tungsten nitride. In other embodiments, the second seed material 133 comprises titanium nitride. In other embodiments, the second seed material 133 comprises at least one element of the first electrode material 134. In some such embodiments, the second seed material 133 comprises a metal silicon nitride (MₓSi_{y}N_{z}, wherein M is a metal, and x and y individually are integers or non-integers depending on the specific metal). The metal may comprise one or more of titanium, tungsten, tantalum, niobium, or molybdenum. In some embodiments, the metal comprises titanium and the second seed material 133 comprises titanium silicon nitride (TiSiN). In some embodiments, the second seed material 133 comprises substantially the same material composition as the seed material 132, such as titanium silicon nitride.

In embodiments where the seed material 132 comprises at least one element of the second insulative material 114 and the third insulative material 116, a thickness T₁ of the seed material 132 between the first electrode material 134 and each of the second insulative material 114 and the third insulative material 116 may be within a range of from about 1.0 Å to about 20.0 Å, such as from about 1.0 Å to about 3.0 Å, from about 3.0 Å to about 5.0 Å, from about 5.0 Å to about 7.0 Å, from about 7.0 Å to about 10.0 Å, from about 10.0 Å to about 15.0 Å, or from about 15.0 Å to about 20.0 Å. In some embodiments, the thickness T₁ is within a range of from about 3.0 Å to about 15.0 Å, such as from about 3.0 Å to about 7.0 Å. In some embodiments, the thickness T₁ is less than about 10.0 Å, such as less than about 7.0 Å, or less than about 5.0 Å. However, the disclosure is not so limited and the thickness T₁ of the seed material 132 may be different than those described.

A vertical thickness (e.g., in the Z-direction) of the second seed material 133 may be substantially the same as the thickness T₁ of the seed material 132.

In some embodiments, the seed material 132 comprises nitrogen atoms, oxygen atoms, and silicon atoms (e.g., SiON). In some such embodiments, an atomic percent of nitrogen in the seed material 132 is within a range of from about 9 atomic percent to about 17 atomic percent, such as from about 9 atomic percent to about 11 atomic percent, from about 11 atomic percent to about 13 atomic percent, or from about 15 atomic percent to about 17 atomic percent nitrogen. An atomic percent of oxygen in the seed material 132 may be within a range of from about 48 atomic percent to about 56 atomic percent, such as from about 48 atomic percent to about 50 atomic percent, from about 50 atomic percent to about 52 atomic percent, from about 52 atomic percent to about 54 atomic percent, or from about 54 atomic percent to about 56 atomic percent. In some embodiments, an atomic percent of silicon in the seed material 132 is within a range of from about 33 atomic percent to about 37 atomic percent, such as from about 33 atomic percent to about 35 atomic percent, or from about 35 atomic percent to about 37 atomic percent.

In some embodiments, the seed material 132 comprises from about 11 atomic percent to about 15 atomic percent nitrogen, from about 50 atomic percent to about 54 atomic percent oxygen, and about 35 atomic percent silicon. In some embodiments, an atomic percent of nitrogen in the seed material 132 is about 0 atomic percent proximate the interface of the seed material 132 and each of the second insulative material 114 and the third insulative material 116 and the atomic percent of the seed material 132 is about 14 atomic percent proximate the interface of the seed material 132 and the first electrode material 134.

In some embodiments, the seed material 132 exhibits a substantially uniform composition throughout a thickness thereof. In other embodiments, the seed material 132 exhibits a gradient of one or more of nitrogen, oxygen, and silicon throughout a thickness thereof. In some embodiments, an atomic percent of nitrogen in the seed material 132 increases with an increasing distance from the second insulative material 114 and the third insulative material 116 to a maximum atomic percent proximate an interface of the seed material 132 and the first electrode material 134. In some such embodiments, an atomic percent of oxygen in the seed material 132 decreases with an increasing distance from the second insulative material 114 and the third insulative material 116 to a minimum atomic percent proximate the interface of the seed material 132 and the first electrode material 134. In some embodiments, the atomic percent of silicon in the seed material 132 is substantially uniform (e.g., constant) throughout a thickness of the seed material 132.

In some embodiments, the second seed material 133 comprises nitrogen atoms and metal atoms (e.g., metal atoms of a metal of the second conductive interconnect structure 112 (e.g., tungsten)). In some such embodiments, an atomic percent of nitrogen in the seed material 132 is within a range of from about 9 atomic percent to about 17 atomic percent, such as from about 9 atomic percent to about 11 atomic percent, from about 11 atomic percent to about 13 atomic percent, or from about 15 atomic percent to about 17 atomic percent nitrogen.

In some embodiments, the additional seed material 133 exhibits a substantially uniform composition throughout a thickness thereof. In other embodiments, the second seed material 133 exhibits a gradient of one or more of nitrogen and metal atoms throughout a thickness thereof. In some embodiments, an atomic percent of nitrogen in the second seed material 133 increases with an increasing distance from the second conductive interconnect structure 112 to a maximum atomic percent proximate an interface of the second seed material 133 and the first electrode material 134. In some such embodiments, an atomic percent of the metal of the second conductive interconnect structure 112 in the second seed material 133 decreases with an increasing distance from the second conductive interconnect structure 112 to a minimum atomic percent proximate the interface of the second seed material 133 and the first electrode material 134.

In other embodiments, the seed material 132 comprises at least one element of the first electrode material 134 and comprises, for example, a metal silicon nitride material. In some embodiments, the seed material 132 comprises at least one element of the first electrode material 134 and at least one element of one or both of the second insulative material 114 and the third insulative material 116. In some embodiments, the seed material 132 comprises titanium silicon nitride. In some such embodiments, the thickness T₁ of the seed material 132 between the first electrode material 134 and each of the second insulative material 114 and the third insulative material 116 the same as that described above.

In some embodiments (e.g., when the seed material 132 comprises TiSiN), the thickness T₁ of the seed material 132 and the thickness T₁ of the second seed material 133 are individually selected such that the seed material 132 and the additional seed material 133 do not exhibit a continuous structure. In some such embodiments, the thickness T₁ of the seed material 132 may be selected such that portions of the seed material 132 do not exhibit so-called “film closure” and portions of the second insulative material 114 or the third insulative material 116 remain exposed through portions of the seed material 132 and portions of the second conductive interconnect structure 112 remain exposed through the second seed material 133. In some such embodiments, portions of the first electrode material 134 directly contact the second insulative material 114 or the third insulative material 116 and other portions of the first electrode material 134 directly contact the seed material 132; and portions of the first electrode material 134 directly contact the second seed material 133 and other portions of the first electrode material 134 directly contact the second conductive interconnect structure 112.

In embodiments where the seed material 132 comprises a metal silicon nitride (e.g., TiSiN), an atomic percent of silicon in the seed material 132 is within a range of from about 1 atomic percent to about 25 atomic percent, such as from about 1 atomic percent to about 3 atomic percent, from about 3 atomic percent to about 5 atomic percent, from about 5 atomic percent to about 10 atomic percent, from about 10 atomic percent to about 15 atomic percent, from about 15 atomic percent to about 20 atomic percent, or from about 20 atomic percent to about 25 atomic percent. In some embodiments, the atomic percent of silicon in the seed material 132 is less than about 15 atomic percent, such as less than about 10 atomic percent, or less than about 5 atomic percent.

In some embodiments, the seed material 132 exhibits a gradient of silicon. In some embodiments, an atomic percent of silicon in the seed material 132 decreases with an increasing distance from the second insulative material 114 and the third insulative material 116 to a minimum atomic percent at the interface of the seed material 132 and the first electrode material 134.

In some embodiments, the second seed material 133 comprises a metal of the second conductive interconnect structure 112 and silicon. By way of non-limiting example, in some embodiments, the second seed material 133 comprises tungsten silicon nitride and the seed material 132 comprises titanium silicon nitride. In yet other embodiments, the seed material 132 and the second seed material 133 individually comprise the same metal silicon nitride (e.g., such as titanium silicon nitride).

The first electrode material 134 may directly contact each of the seed material 132 and the dielectric material 136. The first electrode material 134 may be formed of and include a metal nitride, such as one or more of titanium nitride, tungsten nitride (W₂N, WN, WN₂), tantalum nitride (TaN, TaN), niobium nitride (NbN), and molybdenum nitride (MoN). In some embodiments, the first electrode material 134 comprises titanium nitride.

In some embodiments, the first electrode material 134 comprises at least one element (e.g., chemical element of the periodic table) in common with the seed material 132. In some embodiments, the first electrode material 134 and the seed material 132 each individually comprise nitrogen atoms (e.g., the first electrode material comprises a metal nitride, such as titanium nitride, and the seed material 132 comprises silicon oxynitride). In some embodiments, the first electrode material 134 and the seed material 132 each individually comprise atoms of a metal (e.g., titanium) and nitrogen atoms (e.g., the first electrode material 134 comprises titanium nitride and the seed material 132 comprises titanium silicon nitride). In some such embodiments, the first electrode material 134 and the seed material 132 comprise two elements in common.

An atomic percent of nitrogen in the first electrode material 134 may be greater than an atomic percent of nitrogen in the seed material 132. In some embodiments, the first electrode material 134 comprises about one nitrogen atom for every one metal atom (e.g., every one titanium atom). In other embodiments, the first electrode material 134 comprises about one nitrogen atom for every about two metal atoms. In yet other embodiments, the first electrode material 134 comprises about one metal atom for every about two nitrogen atoms.

In some embodiments, a thickness T₂ of the first electrode material 134 between the seed material 132 and the dielectric material 136 (e.g., in the vertical direction (e.g., in the Z-direction), in the horizontal direction (e.g., in the X-direction)) is less than the thickness T₁ of the seed material 132. By way of non-limiting example, in embodiments where the seed material 132 comprises silicon oxynitride, the thickness T₂ of the first electrode material 134 is less than the thickness T₁ of the seed material 132.

In other embodiments, the thickness T₂ of the first electrode material 134 is greater than the thickness T₁ of the seed material 132. By way of non-limiting example, where the seed material 132 comprises a metal silicon nitride material (e.g., TiSiN), the thickness T₂ of the first electrode material 134 may be greater than the thickness T₁ of the seed material 132. In yet other embodiments, the thickness T₁ of the first electrode material 134 about the same as the thickness T₁ of the seed material 132.

The thickness T₂ of the first electrode material 134 may be within a range of from about 5.0 Å to about 30.0 Å, such as from about 5.0 Å to about 7.0 Å, from about 7.0 Å to about 10.0 Å, from about 10.0 Å to about 15.0 Å, from about 15.0 Å to about 20.0 Å, or from about 20.0 Å to about 30.0 Å. In some embodiments, the thickness T₂ of the first electrode material 134 is within a range of from about 6.0 Å to about 18.0 Å.

In some embodiments, the resistivity of the seed material 132 and the first electrode material 134 in combination is within a range of from about 10,000 μΩ·cm to about 80,000 μΩ·cm, such as from about 10,000 μΩ·cm to about 40,000 μΩ·cm, from about 40,000 μΩ·cm to about 60,000 μΩ·cm, or from about 60,000 μΩ·cm to about 80,000 μΩ·cm and the combined thickness T₂ of the first electrode material 134 and the thickness T₁ of the seed material 132 (e.g., T₁+T₂) is within a range of from about 20 Å to about 25 Å. In some embodiments, the resistivity of the combination of the seed material 132 and the first electrode material 134 is less than about 100,000 μΩ·cm and the combined thickness of the seed material 132 and the first electrode material 134 is less than about 20.0 Å. In some embodiments, the resistivity of the combination of the seed material 132 and the first electrode material 134 is less than about 80,000 μΩ·cm and the combined thickness of the seed material 132 and the first electrode material 134 is less than about 20.0 Å. The sheet resistance was 24,515 ohms/square (in slide 10). In some embodiments, the combined thickness T₂ of the first electrode material 134 and the thickness T₁ of the seed material 132 is about 19.7 Å, and the seed material comprises 133 titanium silicon nitride, and the resistivity of the combination of the seed material 132 and the first electrode material 134 is from about 4,800 μΩ·cm to about 5,000 μΩ·cm and the sheet resistance is from about 24,000 Ω/square (ohms/square) to about 30,000 Ω/square, such as from about 24,000 Ω/square to about 25,000 Ω/square.

The dielectric material 136 may directly contact the first electrode material 134 and the second electrode material 138. The dielectric material 136 may intervene between and isolate the first electrode material 134 from the second electrode material 138.

The dielectric material 136 may be formed of and include one or more of silicon dioxide, phosphosilicate glass, borosilicate glass, borophosphosilicate glass, fluorosilicate glass, silicon nitride, silicon oxynitride, a dielectric carbonitride material (e.g., silicon carbonitride (SiCN)), a dielectric carboxynitride material (e.g., silicon carboxynitride (SiOCN), amorphous carbon, hafnium oxide, zirconium oxide, aluminum oxide (Al₂O₃), lanthanum oxide (La₂O₃), titanium dioxide (TiO₂), tantalum oxide (Ta₂O₅), scandium oxide (Sc₂O₃), and gallium oxide (Ga₂O₃). In some embodiments, the dielectric material 136 comprises a ferroelectric material, such as one or both of hafnium oxide and zirconium oxide doped with one or more dopants (e.g., one or more of yttrium, lanthanum, gadolinium, niobium, tantalum, vanadium, phosphorus, potassium, scandium, rubidium, selenium, tin, magnesium, calcium, barium, indium, and silicon).

The second electrode material 138 may directly overlie and contact the dielectric material 136. The second electrode material 138 may be formed of and include a conductive material, such as one or more of the materials described above with reference to the gate structures 126. By way of non-limiting example, the second electrode material 138 may include one or more of platinum, ruthenium, titanium nitride, tungsten, tungsten nitride, molybdenum, molybdenum nitride, tantalum, tantalum nitride, and aluminum.

In some embodiments, the second electrode material 138 comprises substantially the same material composition as the first electrode material 134. In some embodiments, the first electrode material 134 comprises a metal nitride (e.g., titanium nitride), and the second electrode material 138 comprises the same metal nitride (e.g., titanium nitride). In other embodiments, the second electrode material 138 comprises a different material composition than the first electrode material 134.

In some embodiments, a conductive contact 140 vertically overlies (e.g., in the Z-direction) and is in electrical communication with the second electrode material 138. The conductive contact 140 may be formed of and include a conductive material, such as one or more of the materials described above with reference to the gate structures 126. In some embodiments, the conductive contacts 140 comprise tungsten. In other embodiments, the conductive contacts 140 comprise titanium. In yet other embodiments, the conductive contacts 140 comprise copper.

Forming the storage devices 130 to include the seed material 132 and the second seed material 133 facilitates forming the first electrode material 134 to have a relatively smaller thickness T₂ compared to conventional storage devices 130, while maintaining sufficient electrical properties for operation of the memory cells 110. In some embodiments, forming the seed material 132 over surfaces of the second insulative material 114 and the third insulative material 116 prior to forming the first electrode material 134 facilitates forming the first electrode material 134 to exhibit continuous film properties and improved film coverage when formed at relatively thin thicknesses T₂ (e.g., less than about 20.0 Å, such as less than about 15.0 Å, or even less than about 10.0 Å). In addition, the seed material 132 and the second seed material 133 facilitate forming the first electrode material 134 at relatively thin thicknesses T₂ without a substantial increase in sheet resistance R s and a decrease in conductivity. Further, the seed material 132 and the second seed material 133 facilitate improved uniformity of the first electrode material 134 of different storage devices 130 and between storage devices 130 of different microelectronic devices 100. In some embodiments, the seed material 132 and the second seed material 133 do not substantially affect the resistivity of the first electrode material 134.

Forming the storage devices 130 to include the seed material 132 and the second seed material 133 facilitates forming a nitrogen-containing seed material 132 on which the first electrode material 134 may be formed (e.g., deposited, such as by ALD) and a nitrogen-containing second seed material 133 on which other portions of the first electrode material 134 may be formed. It is believed that the nitrogen of the seed material 132 and the second seed material 133 provides favorable conditions for the growth of the first electrode material 134 (e.g., TiN) by improving substrate surface-adatom (an atom that lies on a crystal surface) interactions between the seed material 132 and the second seed material 133 and precursors used to form the first electrode material 134.

In addition, the seed material 132 and the second seed material 133 may be different than materials formed by decoupled plasma nitridation (DPN) processes. For example, the DPN processes require annealing of the material formed by DPN after the DPN process to stabilize any nitrogen such that the nitrogen is not substantially oxidized in the presence of air. Conventionally, DPN processes are performed at about 900° C. However, if the material formed by DPN is not exposed to annealing conditions, the nitrogen may decay over time (e.g., within two hours). By way of comparison, the seed material 132 and the second seed material 133 including nitrogen described herein is formed at low temperatures (e.g., temperatures within a range of from about 350° C. to about 500° C.) and, therefore, do not result in the microelectronic device 100 being exposed to elevated temperatures. Therefore, the thermal budget of the microelectronic device 100 is maintained without substantially degrading components of the microelectronic device 100.

Although the storage devices 130 have been described and illustrated as including the seed material 132 intervening between the first electrode material 134 and each of the second insulative material 114 and the third insulative material 116, the disclosure is not so limited. FIG. 1C is a simplified cross-sectional view of a storage device 150 according to additional embodiments of the disclosure having an additional seed material 142 in a different location than the seed material 132.

The storage device 150 may replace one or more of the storage devices 130 (FIG. 1A, FIG. 1B) of the memory cells 110 (FIG. 1A). The storage device 150 may be substantially similar to the storage device 130, except that the storage device 150 includes an additional seed material 142 intervening between the dielectric material 136 and the second electrode material 138. In other words, the storage device 150 includes the seed material 132, the second seed material 133, and the additional seed material 142. In other embodiments, the storage device 150 does not include the seed material 132 (and the first electrode 134 intervenes between and contacts each of the second insulative material 114 and the dielectric material 136; and the third insulative material 116 and the dielectric material 136) or the second seed material 133 and includes the additional seed material 142.

The additional seed material 142 may be formed of and include one or more of the materials described above with reference to the seed material 132. In some embodiments, the additional seed material 142 comprises substantially the same material composition as the seed material 132. In other embodiments, the additional seed material 142 comprises a different material composition than the seed material 132.

The additional seed material 142 may directly contact the dielectric material 136 and the second electrode material 138. In some embodiments, the additional seed material 142 comprises one or more of at least one element of the dielectric material 136 and at least one element of the second electrode material 138. In some embodiments, the additional seed material 142 comprises at least one element of the dielectric material 136. By way of non-limiting example, in some embodiments, the additional seed material 142 comprises an oxynitride of the dielectric material 136, such as silicon oxynitride, hafnium oxynitride (HfON), zirconium oxynitride (ZrON), aluminum oxynitride (AlON), lanthanum oxynitride (LaON), titanium oxynitride (TiON), tantalum oxynitride (TaON), scandium oxynitride (ScON), or gallium oxynitride (GaON).

In other embodiments, the additional seed material 142 comprises one or more elements of the second electrode material 138. In some such embodiments, the additional seed material 142 comprises a metal silicon nitride (MSiN, wherein M is a metal). The metal may comprise one or more of titanium, tungsten, tantalum, niobium, or molybdenum. In some embodiments, the metal comprises titanium and the additional seed material 142 comprises titanium silicon nitride (TiSiN).

With reference to FIG. 1C, in embodiments where the additional seed material 142 comprises at least one element of the dielectric material 136, a thickness T₃ of the additional seed material 142 between the dielectric material 136 and the second electrode material 138 may be within a range of from about 1.0 Å to about 20.0 Å, such as from about 1.0 Å to about 3.0 Å, from about 3.0 Å to about 5.0 Å, from about 5.0 Å to about 7.0 Å, from about 7.0 Å to about 10.0 Å, from about 10.0 Å to about 15.0 Å, or from about 15.0 Å to about 20.0 Å. In some embodiments, the thickness T₁ is within a range of from about 3.0 Å to about 7.0 Å. In some embodiments, the thickness T₁ is less than about 10.0 Å, such as less than about 7.0 Å, or less than about 5.0 Å. However, the disclosure is not so limited and the thickness T₃ of the additional seed material 142 may be different than those described.

In some embodiments, the additional seed material 142 comprises nitrogen atoms, oxygen atoms, and atoms of at least one element of the dielectric material 136 (e.g., atoms of at least one of silicon, hafnium, zirconium, aluminum, lanthanum, titanium, tantalum, scandium, and gallium). In some embodiments, the additional seed material 142 comprises nitrogen atoms, oxygen atoms, and atoms of at least one of hafnium and zirconium. In some embodiments, an atomic percent of nitrogen in the additional seed material 142 may be within a range of from about 9 atomic percent to about 17 atomic percent, as described above with reference to the atomic percent of nitrogen in the seed material 132. In addition, an atomic percent of oxygen in the additional seed material 142 may be within a range of from about 48 atomic percent to about 56 atomic percent, as described above with reference to the atomic percent of oxygen in the seed material 132.

The additional seed material 142 may exhibit a substantially uniform composition throughout a thickness thereof. In other embodiments, the additional seed material 142 exhibits a gradient of one or more of nitrogen, oxygen, and the at least one element of the dielectric material 136 throughout a thickness thereof. In some embodiments, an atomic percent of nitrogen in the additional seed material 142 increases with an increasing distance from the dielectric material 136 to a maximum atomic percent of nitrogen proximate an interface of the additional seed material 142 and the second electrode material 138. In some such embodiments, an atomic percent of oxygen in the additional seed material 142 decreases with an increasing distance from the dielectric material 136 to a minimum atomic percent of oxygen proximate the interface of the additional seed material 142 and the second electrode material 138. In some embodiments, the atomic percent of the at least one element of the dielectric material 136 in the additional seed material 142 is substantially uniform (e.g., constant) throughout a thickness of the additional seed material 142.

In other embodiments, the additional seed material 142 comprises at least one element of the second electrode material 138 and comprises at least one element of the dielectric material 136 (e.g., at least one of silicon, hafnium, zirconium, aluminum, lanthanum, titanium, tantalum, scandium, and gallium) and the metal of the second electrode material 138 (e.g., titanium). In some embodiments, the additional seed material 142 comprises titanium silicon nitride and further comprises atoms of one or more of hafnium, zirconium, aluminum, lanthanum, titanium, tantalum, scandium, and gallium.

In some embodiments, an atomic percent of silicon in the additional seed material 142 is within a range of from about 1 atomic percent to about 25 atomic percent, as described above with reference to the atomic percent of silicon in the seed material 132.

In some such embodiments, the thickness T₃ of the additional seed material 142 is within a range of from about 3.0 Å to about 20.0 Å, as described above with reference to the thickness T₁ of the seed material 132. In some embodiments, the thickness T₃ of the additional seed material 142 is substantially the same as the thickness T₁ of the seed material 132. In other embodiments, the thickness T₃ of the additional seed material 142 is greater than the thickness T₁ of the seed material 132.

In some embodiments, the additional seed material 142 exhibits a gradient of silicon. In some embodiments, an atomic percent of silicon in the additional seed material 142 decreases with an increasing distance from the dielectric material 136 to a minimum atomic percent of silicon at the interface of the additional seed material 142 and the second electrode material 138. In other embodiments, an atomic percent of silicon in the additional seed material 142 increases with an increasing distance from the dielectric material 136 to a maximum atomic percent of silicon at the interface of the additional seed material 142 and the second electrode material 138.

The second electrode material 138 may directly contact the additional seed material 142. The additional seed material 142 may directly contact and vertically intervene (e.g., in the Z-direction) and horizontally intervene (e.g., in the X-direction) between the dielectric material 136 and the second electrode material 138.

In some embodiments, an atomic percent of nitrogen in the second electrode material 138 is greater than an atomic percent of nitrogen in the additional seed material 142.

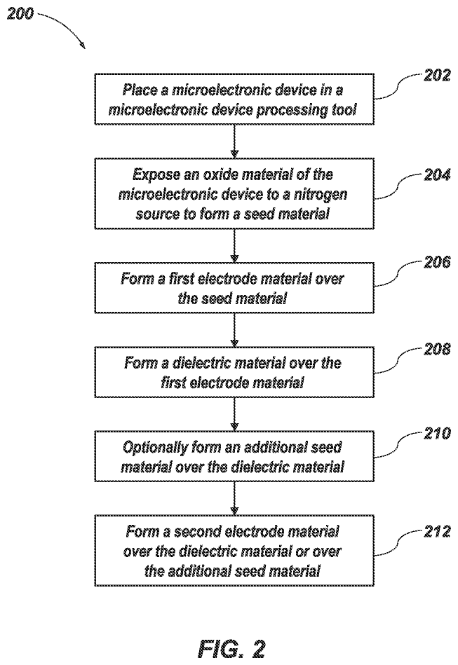

FIG. 2 is a simplified flow diagram illustrating a method 200 of forming the storage devices 130, 150, in accordance with embodiments of the disclosure. The method comprises act 202 including placing a microelectronic device (e.g., the microelectronic device 100) in a microelectronic device processing tool; act 204 including exposing an oxide material of the microelectronic device (e.g., one or both of the second insulative material 114 and the third insulative material 116) to a nitrogen source to form a seed material (e.g., the seed material 132); act 206 including forming a first electrode material (e.g., the first electrode material 134) over the seed material; act 208 including forming a dielectric material (e.g., the dielectric material 136) over the first electrode material; act 210 including optionally forming an additional seed material (e.g., the additional seed material 142) over the dielectric material 136; and act 212 including forming a second electrode material (e.g., the second electrode material 138) over the dielectric material or the additional seed material.

Act 202 includes placing a microelectronic device (e.g., the microelectronic device 100) in a microelectronic processing tool. The microelectronic processing tool may be configured to perform one or more of ALD, PEALD, CVD, PVD, LPCVD, PECVD, or PEALD. In some embodiments, the microelectronic processing tool comprises an ALD tool. In some embodiments, the microelectronic device is located within a chamber of the microelectronic processing tool (e.g., an ALD chamber) prior to forming the storage devices 130, 150. For example, portions of the microelectronic device (e.g., the second insulative material 114, the third insulative material 116, the second conductive interconnect structures 112) may be formed within the microelectronic processing tool prior to conducting act 202. The storage devices 130, 150 are formed in openings (not shown) in the third insulative material 116. The openings may be formed by conventional techniques.

Act 204 includes exposing an oxide material of the microelectronic device (e.g., one or both of the second insulative material 114 and the third insulative material 116) to a nitrogen source to form a seed material (e.g., the seed material 132) on one or both of the second insulative material 114 and the third insulative material 116. The microelectronic device may be located within a processing chamber of the microelectronic device processing tool. In some embodiments, exposing the oxide material to the nitrogen source comprises nitridizing surfaces of the oxide material. For example, a portion of the oxide material may be exposed to the nitrogen source, converting the oxide material to a nitridized oxide material (e.g., a silicon oxynitride in embodiments where the oxide material comprises silicon oxide (e.g., silicon dioxide)). In some embodiments, nitridizing the surface of the oxide material comprises forming silicon oxynitride from the oxide material. In some embodiments, such as where the second conductive interconnect structure 112 does not comprise an oxide, the seed material 132 is not formed on surfaces of the second conductive interconnect structure 112.

In some embodiments, exposing the microelectronic device to the nitrogen source comprises placing the microelectronic device in an ALD chamber. The nitrogen source may include one or more of nitrogen gas (N₂), ammonia (NH₃), and hydrazine (N₂H₄). In some embodiments, exposing the microelectronic device to the nitrogen source comprises exposing the microelectronic device to a mixture comprising nitrogen and ammonia.

In some embodiments, a ratio of N₂ to NH₃ in the nitrogen source may be within a range of from about 0.1:1.0 to about 430:1.0. Stated another way for every about 1.0 molecule of NH₃, the nitrogen source includes from about 0.1 molecule of N₂ to about 430 molecules of N₂. In other words, for every about 1.0 standard cubic centimeters per minute (sccm) flow of ammonia, the nitrogen source includes from about 0.1 sccm nitrogen to about 430 sccm nitrogen.

In some embodiments, the nitrogen source is provided to the processing chamber as a plasma. In other embodiments, the nitrogen source is provided to the processing chamber as a non-plasma gas. In embodiments where the nitrogen source is provided as a plasma, a flow rate of nitrogen plasma may be within a range of from about 50 sccm to about 15,000 sccm. In some such embodiments, the flow rate of ammonia plasma may be within a range of from about 35 sccm to about 4,000 sccm. Thus, the flow rate of ammonia plasma/nitrogen plasma is within a range of from about 35 sccm/50 sccm to about 4,000 sccm/15,000 sccm.

In some embodiments, providing the nitrogen source as a plasma facilitates formation of the seed material 132, 142 at a relatively low temperature. For example, the thermal dissociation temperature of ammonia is from about 449° C. to about 499° C. and the thermal dissociation temperature of nitrogen is greater than about 3,200° C. Providing the nitrogen and the ammonia as a plasma facilitates forming the seed material 132, 143 at temperatures lower than the dissociation temperature of ammonia and nitrogen gas. The temperature of the processing chamber during formation of the seed material (e.g., the temperature at which the nitrogen source is provided to the processing chamber) may be within a range of from about 0° C. to about 700° C., such as from about 0° C. to about 100° C., from about 100° C. to about 200° C., from about 200° C. to about 300° C., from about 300° C. to about 400° C., from about 400° C. to about 500° C., or from about 500° C. to about 700° C. In some embodiments, the temperature of the processing chamber is less than about 449° C., such as less than about 400° C., or less than about 350° C. In some embodiments, the temperature of the processing chamber is about 400° C.

In embodiments where the nitrogen source is provided as a non-plasma gas, the temperature of the processing chamber is within a range of from about 300° C. to about 500° C. In some embodiments, the temperature is from about 450° C. to about 500° C.

In embodiments where the nitrogen source is provided as a plasma, the frequency of the high power source is about 13.56 MHz and the frequency of the low power source is about 350 Hz. The high frequency (HF) power may be within a range of from about 100 W to about 3.0 kW. The low frequency (LF) power may be within a range of from about 100 W to about 900 W. In some embodiments, the HF power is about 400 W and the LF power is about 0 W.

In embodiments where the nitrogen source is provided as a plasma, a pressure of the processing chamber may be within a range of from about 500 mTorr to about 10.0 Torr. In embodiments where the nitrogen source is provided as a non-plasma gas, the pressure of the processing chamber may be within a range of from about 0 Torr to about 100 Torr.

In some embodiments, the oxide material is exposed for a duration within a range of from less than 1 second to about 60 minutes. In some embodiments, the duration is from about 2.0 seconds to about 30 seconds. In some embodiments, providing the nitrogen source as a plasma facilitates forming the seed material faster than the seed material would be formed with a non-plasma nitrogen source and at lower temperatures.

In some embodiments, act 204 further includes exposing a conductive material (e.g., the second conductive interconnect structures 112) to the nitrogen source to form a second seed material (e.g., the second seed material 133).

With continued reference to FIG. 2, act 206 includes forming a first electrode material (e.g., the first electrode material 134) over the seed material. The first electrode material may be formed in the processing chamber by, for example, exposing the seed material to precursors for forming the first electrode material. For example, if the first electrode material comprises titanium, the seed material may be sequentially exposed to a titanium-containing precursor (e.g., titanium tetrachloride (TiCl₄), tetrakis(dimethylamino)titanium (TDMAT), tetrakisdiethylamidotitanium (TDEAT)) followed by exposing the seed material to a nitrogen-containing precursor (e.g., nitrogen gas, ammonia).

Act 208 includes forming a dielectric material (e.g., the dielectric material 136) over the first electrode material. The dielectric material may be formed within the processing chamber by exposing the first electrode material to one or more precursors for forming the dielectric material. Methods of forming a dielectric material are known in the art and are not described in detail herein.

Act 210 includes optionally forming an additional seed material (e.g., the additional seed material 142) over the dielectric material and may be substantially similar to act 204. Act 212 includes forming a second electrode material (e.g., the second electrode material 138) over either the dielectric material or the additional seed material and is substantially similar to act 206.

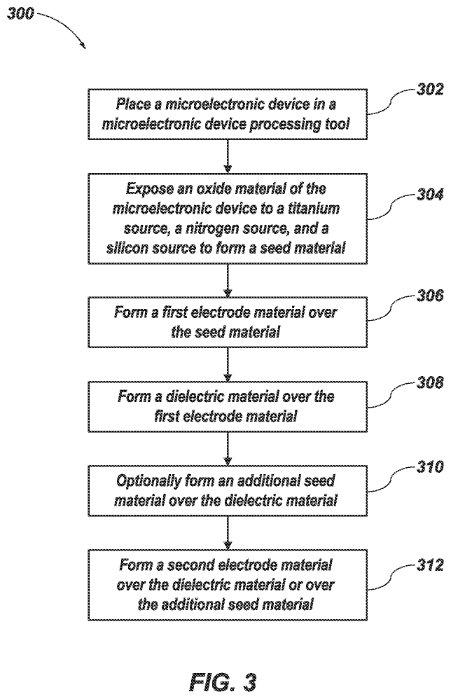

FIG. 3 is a simplified flow diagram illustrating a method 300 of forming the storage devices 130, 150, in accordance with embodiments of the disclosure. The method comprises act 302 including placing a microelectronic device (e.g., the microelectronic device 100) in a microelectronic device processing tool; act 304 including exposing an oxide material of the microelectronic device (e.g., one or both of the second insulative material 114 and the third insulative material 116) to a titanium source, a nitrogen source, and a silicon source to form a seed material (e.g., the seed material 132) on an oxide material of the microelectronic device; act 306 including forming a first electrode material (e.g., the first electrode material 134) over the seed material; act 308 including forming a dielectric material (e.g., the dielectric material 136) over the first electrode material; act 310 including optionally forming an additional seed material (e.g., the additional seed material 142) over the dielectric material 136; and act 312 including forming the second electrode material (e.g., the second electrode material 138) over the dielectric material or the additional seed material.

Act 302 may be substantially the same as act 202 described above with reference to FIG. 2.

Act 304 includes exposing the microelectronic device (e.g., one or both of the second insulative material 114 and the third insulative material 116) to a titanium source, a nitrogen source, and a silicon source to form a seed material (e.g., the seed material 132) on an oxide material of the microelectronic device. In some embodiments, the oxide material is sequentially exposed to the titanium source, the nitrogen source, and the silicon source. In some embodiments, the seed material comprises titanium silicon nitride.

The titanium source may include one or more of TiCl₄, TDMAT, and TDEAT. The nitrogen source may include one or more of N₂, NH₃, and N₂H₄. The silicon source may include one or both of silane (SiH₄) disilane (Si₂H₆), and dichlorosilane (SiH₂Cl₂). In some embodiments, the titanium source comprises TiCl₄. In some embodiments, the nitrogen source comprises ammonia. In other embodiments, the nitrogen source comprises ammonia and nitrogen gas. In some embodiments, the silicon source comprises silane. In other embodiments, the silicon source comprises disilane.

In some embodiments, act 304 includes performing one or more cycles of exposing the microelectronic device to the titanium source; purging the processing chamber of excess (e.g., unreacted) titanium source; exposing the microelectronic device to the nitrogen source; purging the processing chamber of excess (e.g., unreacted) nitrogen source; exposing the microelectronic device to the silicon source; purging the processing chamber of excess (e.g., unreacted) silicon source; exposing the microelectronic device to the nitrogen source; purging the processing chamber of excess (e.g., unreacted) nitrogen source; and repeating the cycle (e.g., exposing the microelectronic device to the titanium source; purging; exposing the microelectronic device to the nitrogen source; purging; exposing the microelectronic device to the silicon source; purging; exposing the microelectronic device to the nitrogen source; and purging) one or more additional times until the seed material is formed to a desired thickness. In some embodiments, the seed material comprises titanium silicon nitride.

In other embodiments, act 304 includes performing one or more cycles of exposing the microelectronic device to the titanium source; purging the processing chamber of the titanium source; exposing the microelectronic device to the silicon source; purging the processing chamber of the silicon source; and repeating the cycle (e.g., exposing the microelectronic device to the titanium source; purging; exposing the microelectronic device to the nitrogen source; purging; exposing the microelectronic device to the silicon source; and purging) one or more additional times until the seed material is formed.

In yet other embodiments, act 304 includes performing one or more cycles of exposing the microelectronic device to a titanium source; purging the processing chamber of the titanium source; exposing the microelectronic device to a silicon source; purging the processing chamber of the silicon source; exposing the microelectronic device to a nitrogen source; purging the processing chamber of the nitrogen source; and repeating the cycle (e.g., exposing the microelectronic device to the titanium source; purging; exposing the microelectronic device to the silicon source; purging; exposing the microelectronic device to the nitrogen source; and purging) one or more additional times until the seed material is formed.

In further embodiments, act 304 includes forming titanium silicon nitride by PVD, such as by exposing a titanium target to the microelectronic device to the nitrogen source and the silicon source to form the titanium silicon nitride on the surfaces of the microelectronic device.

The temperature of the processing chamber during the formation of the seed material may be within a range of from about 300° C. to about 550° C. In some embodiments, the temperature is about 400° C.

The pressure of the processing chamber may be within a range of from about 0 Torr to about 100 Torr.

The flow rate of each of the titanium source, the nitrogen source, and the silicon source may individually be within a range of from about 5 sccm to about 20,000 sccm.

In some embodiments, the microelectronic device is exposed to the titanium source, the silicon source, and the nitrogen source individually for a duration within a range of from less than 1 second to about 60 minutes. In some embodiments, the duration is from about 2.0 seconds to about 30 seconds.

In some embodiments, act 304 includes exposing a conductive material (e.g., the second conductive interconnect structures 112) to one or more of the titanium source, the nitrogen source, and the silicon source.

Act 306, 308, and 310 are individually substantially the same as act 206, 208, and 210, respectively described above with reference to FIG. 2.

Although the methods 200, 300 have been described and illustrated as forming the seed material on an oxide material and as a portion of an electrode of a capacitor, the disclosure is not so limited. In some embodiments, the methods 200, 300 may be used to selectively form continuous materials at a relatively low thickness (e.g., within a range of from about 6.0 Å to about 18.0 Å, such as less than 1.0 Å, less than 15.0 Å, or even less than 10.0 Å). The seed material may form a template for selective deposition of another material (e.g., a metal or a metal nitride, such as titanium nitride) on the surface of the seed material. The seed material facilitates growth of the another material at a faster rate (e.g., about 1.5 times to about 2.0 times faster) on the seed material compared to growth of the another material on surfaces other than the seed material. Accordingly, the seed material may be used to facilitate selective deposition of other materials. In some embodiments, the seed material facilitates surface coverage of the another material (e.g., TiN) to greater than about 90 percent at the relatively thin thicknesses (e.g., within a range of from about 6.0 Å to about 18.0 Å) compared to the surface coverage of the another material at the relatively thin thicknesses, which may be about 50 percent. In some embodiments, the seed material may be formed on one or more surfaces of an oxide material (e.g., one or more of an insulative oxide material (e.g., silicon dioxide), a metal oxide, a conductive metal oxide) and a metal nitride (e.g., titanium nitride) may be formed on the seed material. The seed material may comprise, for example, one or more of a nitride of the oxide material, an oxynitride of the oxide material, and a metal silicon nitride of the oxide material.

Although the seed material 132 and the another seed material 142 have been described and illustrated as being used in the microelectronic devices 100 and storage devices 130, the disclosure is not so limited. The seed material 132 and/or the another seed material 142 may be used when forming a metal nitride (e.g., titanium nitride) or a doped metal nitride (e.g., doped titanium nitride) that at least partially overlies an oxide material (e.g., silicon dioxide), such as in DRAM, HRAM, FeRAM, or other structures. The seed material 132 and the another seed material 142 may improve the uniformity of the respective first electrode material 134 and the second electrode material 138 and reduce variations across the thicknesses thereof within the same device or in different wafers processed separately compared to devices formed without the seed material 132 or the another seed material 142. Improving the uniformity of such materials reduces the amount of devices that are formed that do not meet quality standards.

Thus, in accordance with some embodiments, a microelectronic device comprises an access device comprising a source region and a drain region spaced from the source region, an insulative material vertically adjacent to the access device, and a capacitor within the insulative material and in electrical communication with the access device. The capacitor comprises a material comprising silicon oxynitride or titanium silicon nitride over surfaces of the insulative material, a first electrode comprising titanium nitride on the material, a dielectric material on the first electrode, and a second electrode on the dielectric material.

Furthermore, in accordance with additional embodiments of the disclosure, a method of forming a microelectronic device comprises forming a capacitor over an oxide material. Forming the capacitor comprises forming an electrode over the oxide material. Forming the electrode comprises exposing the oxide material to a nitrogen-containing gas to form a seed material comprising one of silicon oxynitride or titanium silicon nitride over the oxide material, and after forming the seed material, exposing the seed material to a titanium-containing gas to form titanium nitride over the seed material.

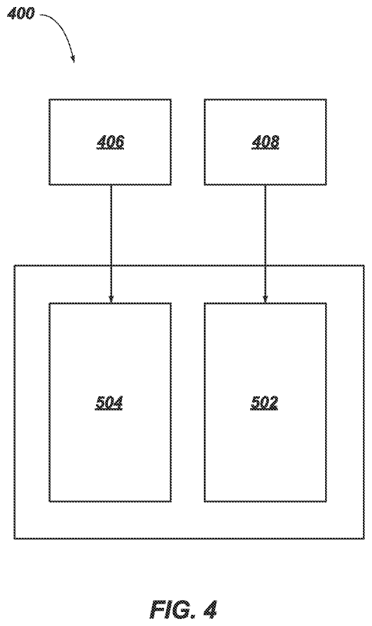

Structures, assemblies, and devices in accordance with embodiments of the disclosure may be included in electronic systems of the disclosure. For example, FIG. 4 is a block diagram of an illustrative electronic system 400 according to embodiments of disclosure. The electronic system 400 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 400 includes at least one memory device 402. The memory device 402 may comprise, for example, an embodiment of one or more of a microelectronic device including storage devices (e.g., storage devices 130, 150) previously described herein with reference to FIG. 1A through FIG. 1C. The electronic system 400 may further include at least one electronic signal processor device 404 (often referred to as a “microprocessor”). The electronic signal processor device 404 may, optionally, include an embodiment of one or more of a microelectronic device structure, a microelectronic device structure assembly, a relatively larger microelectronic device structure assembly, and a microelectronic device including the storage devices (e.g., storage devices 130, 150) previously described herein with reference to FIG. 1A through FIG. 1C. While the memory device 402 and the electronic signal processor device 404 are depicted as two (2) separate devices in FIG. 4, in additional embodiments, a single (e.g., only one) memory/processor device having the functionalities of the memory device 402 and the electronic signal processor device 404 is included in the electronic system 400. In such embodiments, the memory/processor device may include one or more microelectronic devices including storage devices (e.g., storage devices 130, 150) previously described herein with reference to FIG. 1A through FIG. 1C. The electronic system 400 may further include one or more input devices 406 for inputting information into the electronic system 400 by a user, such as, for example, a mouse or other pointing device, a keyboard, a touchpad, a button, or a control panel. The electronic system 400 may further include one or more output devices 408 for outputting information (e.g., visual or audio output) to a user such as, for example, one or more of a monitor, a display, a printer, an audio output jack, and a speaker. In some embodiments, the input device 406 and the output device 408 may comprise a single touchscreen device that may be used both to input information to the electronic system 400 and to output visual information to a user. The input device 406 and the output device 408 may communicate electrically with one or more of the memory device 402 and the electronic signal processor device 404.

Thus, in accordance with embodiments of the disclosure, an electronic system comprises an input device, an output device, a processor device operably coupled to the input device and the output device, and a memory device operably coupled to the processor device. The memory device comprises an insulative material overlying access devices, and a capacitor vertically extending through the insulative material and in electrical communication with one of the access devices. The capacitor comprises a seed material comprising nitrogen atoms and at least one element of the insulative material, a first electrode comprising a metal nitride on the seed material, a dielectric material on the first electrode, and a second electrode on the dielectric material.

Thus, in accordance with additional embodiments of the disclosure, an electronic system comprises an input device, an output device, a processor device operably coupled to the input device and the output device, and a memory device operably coupled to the processor device. The memory device comprises an oxide insulative material overlying access devices, a seed material comprising nitrogen atoms and at least one element of the oxide insulative material, and a conductive material comprising a metal nitride on the seed material.

### EXAMPLES

### Example 1

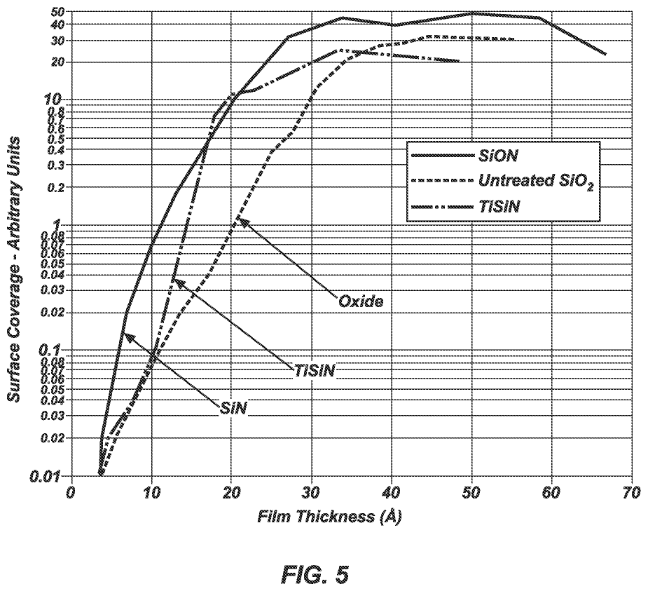

Titanium nitride was formed on silicon dioxide surfaces that had not been exposed to pretreatment; titanium nitride was formed on silicon dioxide surfaces that had been exposed to a pretreatment process to form a silicon oxynitride seed material, as described above; and titanium nitride was formed on silicon dioxide surfaces that had been exposed to a pretreatment process to form a titanium silicon nitride seed material, as described above. The surface coverage (e.g., the amount of the initial silicon dioxide surface) that was covered with the titanium nitride was measured for the pretreated surfaces including the silicon oxynitride, the pretreated surfaces including the titanium silicon nitride, and the untreated surfaces as a function of thickness of the titanium nitride. FIG. 5 is a graph illustrating the relationship of the thickness of the deposited titanium nitride material and the surface coverage for the pretreated surfaces compared to the untreated surfaces. With reference to FIG. 5, at relatively lower thicknesses of the titanium nitride film (e.g., thicknesses less than about 30.0 Å, such as about 20.0 Å) the pretreated surfaces exhibited significantly greater surface coverage than the untreated surfaces. For example, at about 20 Å, the surface coverage of the titanium nitride formed on the pretreated surface comprising titanium silicon nitride and on the pretreated surface comprising silicon oxynitride was about ten times greater than the surface coverage of the untreated silicon dioxide. At about 30 Å, the surface coverage of the titanium nitride was about two times greater for the titanium nitride formed on the pretreated surface comprising titanium silicon nitride than the surface coverage of titanium nitride formed on the untreated surface. At 30.0 Å, the surface coverage of the titanium nitride was about 3.5 times greater for the titanium nitride formed on the pretreated surface comprising silicon oxynitride than the surface coverage of titanium nitride formed on the untreated surface.

### Example 2

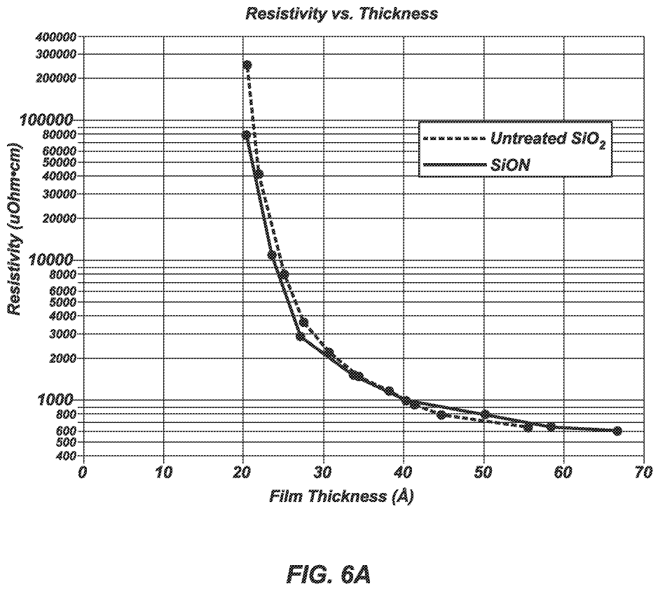

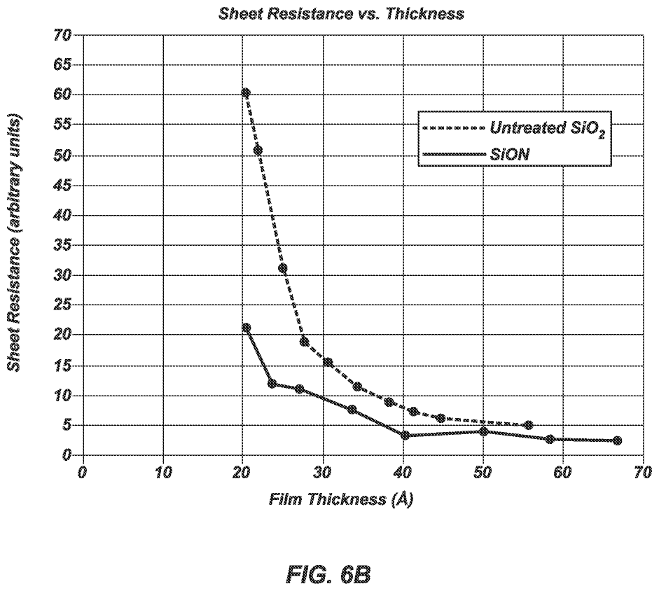

The resistivity and the sheet resistance of titanium nitride formed on the pretreated surface comprising silicon oxynitride over a silicon dioxide surface was measured and compared to the resistivity of titanium nitride formed on an untreated silicon dioxide surface. FIG. 6A is a graph comparing the resistivity of the titanium nitride formed on the pretreated silicon oxynitride surface to the resistivity of the titanium nitride formed on the untreated silicon dioxide surface; and FIG. 6B is a graph comparing the sheet resistance of the titanium nitride formed on the pretreated silicon oxynitride surface to the sheet resistance of the titanium nitride formed on the untreated silicon dioxide surface.

With reference to FIG. 6A, at relatively lower thicknesses, such as at 20 Å, the resistivity of titanium nitride formed on an untreated SiO₂ surface was about three times the resistivity of the titanium nitride formed on a treated SiO₂ surface comprising SiON. The resistivity of the titanium nitride formed on the untreated SiO₂ surface was greater than the resistivity of the titanium nitride formed on the SiON surface at thicknesses less than about 35.0 Å. With reference to FIG. 6B, at about 20 Å, the sheet resistance of the titanium nitride formed on the untreated SiO₂ surface was about three times the sheet resistance of the titanium nitride formed on a treated SiO₂ surface comprising SiON. The sheet resistance of the titanium nitride formed on the untreated SiO₂ surface was greater than the sheet resistance of the titanium nitride formed on the SiON surface at thicknesses less than about 60 Å.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device comprising:
an access device comprising a source region and a drain region spaced from the source region;
an insulative material vertically adjacent to the access device; and
a capacitor within the insulative material and in electrical communication with the access device, the capacitor comprising:
a material comprising silicon oxynitride or titanium silicon nitride over surfaces of the insulative material;
a first electrode comprising titanium nitride on the material;
a dielectric material on the first electrode; and
a second electrode on the dielectric material.

2. The microelectronic device of claim 1, wherein a thickness of the first electrode is within a range of from about 5.0 Å to about 30.0 Å.

3. The microelectronic device of claim 1, wherein the dielectric material comprises one or more of silicon dioxide, silicon nitride, hafnium oxide, zirconium oxide, aluminum oxide, lanthanum oxide, titanium dioxide, tantalum oxide, scandium oxide, and gallium oxide.

4. The microelectronic device of claim 1, wherein the material comprises titanium silicon nitride and has a thickness within a range of from about 3.0 Å to about 15.0 Å.

5. The microelectronic device of claim 1, wherein the titanium silicon nitride comprises a silicon content within a range of from about 1 atomic percent to about 25 atomic percent.

6. The microelectronic device of claim 1, wherein the material has a silicon content of less than about 15 atomic percent.

7. The microelectronic device of claim 1, wherein the material comprises silicon oxynitride and has a thickness within a range of from about 1.0 Å to about 20.0 Å.

8. The microelectronic device of claim 1, wherein the material comprises silicon oxynitride and exhibits an atomic percent of nitrogen increasing with an increasing distance from the surfaces of the insulative material.

9. The microelectronic device of claim 1, wherein the material comprises silicon oxynitride and comprises:
from about 9 atomic percent nitrogen to about 17 atomic percent nitrogen; and
from about 48 atomic percent oxygen to about 56 atomic percent oxygen.

10. The microelectronic device of claim 1, further comprising an additional material comprising silicon oxynitride or titanium silicon nitride between the dielectric material and the second electrode.

11. The microelectronic device of claim 1, wherein the first electrode has a thickness less than about 20.0 Å and exhibits a resistivity less than about one-third a resistivity of a titanium nitride material overlying a silicon dioxide material and having a same thickness as the first electrode.

12. An electronic system, comprising:
an input device;
an output device;
a processor device operably coupled to the input device and the output device; and
a memory device operably coupled to the processor device and comprising:
an oxide insulative material overlying access devices;
a seed material comprising nitrogen atoms and at least one element of the oxide insulative material; and
a conductive material comprising a metal nitride on the seed material;

13. The electronic system of claim 12, wherein the seed material further comprises atoms of the metal of the metal nitride.

14. The electronic system of claim 12, wherein an atomic percent of nitrogen in the seed material decreases with an increasing distance from the insulative material.

15. A method of forming a microelectronic device, the method comprising:
forming a capacitor over an oxide material, forming the capacitor comprising:
forming an electrode over the oxide material, forming the electrode comprising:
exposing the oxide material to a nitrogen-containing gas to form a seed material comprising one of silicon oxynitride or titanium silicon nitride over the oxide material; and
after forming the seed material, exposing the seed material to a titanium-containing gas to form titanium nitride over the seed material.

16. The method of claim 15, further comprising exposing the oxide material to an additional titanium-containing gas and a silicon-containing gas to form a seed material comprising titanium silicon nitride.

17. The method of claim 15, wherein forming a titanium nitride material over the seed material comprises sequentially exposing the seed material to the titanium-containing gas and an additional nitrogen-containing gas.

18. The method of claim 15, wherein exposing the oxide material to a nitrogen-containing gas comprises exposing the oxide material to one or more of ammonia, nitrogen, and hydrazine.

19. The method of claim 15, wherein exposing the oxide material to a nitrogen-containing gas comprises exposing the oxide material to a plasma comprising ammonia and nitrogen at a power within a range of from about 100 W to about 3.0 kW.

20. The method of claim 15, wherein exposing the oxide material to a nitrogen-containing gas comprises exposing the oxide material to the nitrogen-containing gas at a temperature of between about 350° C. and about 500° C.
